(19) United States
(12) Patent Application Publication
(10) Pub. No.: US 2021/0168338 A1
(43) Pub. Date: Jun. 3, 2021

(54) LIGHT EMITTING APPARATUS AND PROJECTOR

(71) Applicant: Seiko Epson Corporation, Tokyo (JP)

(72) Inventor: Yoshitaka ITOH, Matsumoto (JP)

(21) Appl. No.: 17/104,863

(22) Filed: Nov. 25, 2020

(30) Foreign Application Priority Data
Nov. 29, 2019 (JP) 2019-216437
Sep. 23, 2020 (JP) 2020-158302

(51) Int. Cl. H04N 9/31

(52) U.S. Cl. CPC H04N 9/3152

(57) ABSTRACT

A light emitting apparatus according to an aspect of the present disclosure includes a base and a plurality of resonators provided at a first surface of the base. The plurality of resonators each include a photonic crystal structure having a periodic structure. The plurality of resonators form a light emission region that emits light resonate due to the periodic structure, and the plurality of resonators include a first resonator and a second resonator. The distance from the center of the light emission region to the second resonator is longer than the distance from the center of the light emission region to the first resonator. The resonance length of the second resonator is longer than the resonance length of the first resonator.

The present application is based on, and claims priority from JP Application Serial Number 2019-216437, filed Nov. 29, 2019, and Serial Number 2020-158302, filed Sep. 23, 2020, the disclosures of which are hereby incorporated by reference herein in their entireties.

### BACKGROUND

### 1. Technical Field

The present disclosure relates to a light emitting apparatus and a projector.

### 2. Related Art

There has been a known light emitting apparatus using a photonic crystal. For example, JP-A-2009-43918 discloses a surface emitting laser having a structure which includes a two-dimensional photonic crystal and a one-dimensional photonic crystal and in which a photonic band edge of the one-dimensional photonic crystal reflects light propagating in the in-plane directions of the two-dimensional photonic crystal.

A study on configuration of a compact projector using a surface light source, such as that described above has been conducted. In this case, a light modulating apparatus can be efficiently illuminated if the surface light source can be disposed in a position nearest to the light modulating apparatus. However, to provide a space for cooling the light modulating apparatus or a space for disposing a variety of optical elements, for example, a lens, the surface light source and the light modulating apparatus need to be so disposed as to be separate from each other by a predetermined distance. For example, when the light modulating apparatus is formed of a liquid crystal display device, a space for disposing a polarizer is required between the surface light source and the liquid crystal display device.

When the light flux emitted from the surface light source is not a parallelized light flux but is a divergent light flux, the diameter and outer shape of the light flux change as the distance from the surface light source increases. Therefore, when the light modulating apparatus is disposed in a position remote from the surface light source, the outer shape of the light flux incident on the light modulating apparatus differs from the outer shape of the light flux immediately after the light flux is emitted from the surface light source. An image formation region of the light modulating apparatus has a rectangular shape in many cases. Even when the surface light source is configured to have a rectangular light emission region in accordance with the rectangular image formation region, the outer shape of the light flux is so deformed as to approach a circular shape as the distance from the surface light source increases. As a result, the outer shape of the light flux does not match with the shape of the image formation region of the light modulating apparatus, resulting in a problem of insufficient illumination of the image formation region.

### SUMMARY

To solve the problem described above, a light emitting apparatus according to an aspect of the present disclosure includes a base and a plurality of resonators provided at a first surface of the base. The plurality of resonators each include a photonic crystal structure having a periodic structure. The plurality of resonators form a light emission region that emits light that the periodic structure allows to resonate, and the plurality of resonators include a first resonator and a second resonator. A distance from a center of the light emission region to the second resonator is longer than a distance from the center of the light emission region to the first resonator. A resonance length of the second resonator is longer than the resonance length of the first resonator.

In the light emitting apparatus according to the aspect of the present disclosure, the light emission region may have a plurality of divided regions concentric around the center. The plurality of divided regions may include a first divided region and a second divided region. A plurality of the first resonators may be provided in the first divided region, and a plurality of the second resonators may be provided in the second divided region. The plurality of first resonators in the first divided region may have the same resonance length, and the plurality of second resonators in the second divided region may have the same resonance length.

In the light emitting apparatus according to the aspect of the present disclosure, an intensity distribution of a light flux emitted from the light emission region may be so shaped that the intensity at a peripheral portion of the light emission region is higher than the intensity at a central portion of the light emission region.

In the light emitting apparatus according to the aspect of the present disclosure, the plurality of resonators may be provided on a first surface of the base via at least one intermediate base.

In the light emitting apparatus according to the aspect of the present disclosure, the at least one intermediate base may include a first intermediate base and a second intermediate base, the first resonator may be provided on the first intermediate base, and the second resonator may be provided on the second intermediate base.

In the light emitting apparatus according to the aspect of the present disclosure, the plurality of resonators may include a plurality of the first resonators and a plurality of the second resonators, the plurality of first resonators may be provided on the first intermediate base, and the plurality of second resonators are provided on the second intermediate base.

A projector according to another aspect of the present disclosure includes the light emitting apparatus according to the aspect of the present disclosure, a light modulating apparatus that modulates light emitted from the light emitting apparatus in accordance with image information to produce image light, and a projection optical apparatus that projects the image light emitted from the light modulating apparatus.

In the projector according to the aspect of the present disclosure, a planar shape of the light emission region may be similar to a planar shape of an image formation region of the light modulating apparatus.

The projector according to the aspect of the present disclosure may further include a relay system provided between the light emitting apparatus and the light modulating apparatus.

The projector according to the aspect of the present disclosure may further include a light guide provided between the light emitting apparatus and the light modulating apparatus.

### BRIEF DESCRIPTION OF THE DRAWINGS

FIG. 1 is a schematic configuration diagram of a projector according to a first embodiment.

FIG. 2 is a plan view of a light emitter in the first embodiment.

FIG. 3 is a plan view of a resonator.

FIG. 4 is a cross-sectional view of the resonator taken along the line IV-IV in FIG. 3.

FIG. 5 shows the light orientation angle of light emitted from the resonator.

FIG. 6 shows the light orientation angles of the light emitted from a plurality of resonators located in different positions in a light emission region.

FIG. 7 shows the positions where the light emitted from the plurality of resonators reach an image formation region of a light modulating apparatus.

FIG. 8 shows the planar shape and the intensity distribution of a light flux.

FIG. 9 shows the planar shape and the intensity distribution of a light flux from a light emitting apparatus according to Comparative Example.

FIG. 10 is a plan view of a light emitting apparatus according to a second embodiment.

FIG. 11 shows the relationship between the distance from the center of the light emission region and the size of the resonators.

FIG. 12 is a cross-sectional view of a light emitting apparatus according to a third embodiment.

FIG. 13 is a cross-sectional view of a light emitting apparatus according to a fourth embodiment.

FIG. 14 is a cross-sectional view of a light emitting apparatus according to a variation.

FIG. 15 is a cross-sectional view of a light emitting apparatus showing a first configuration example of an electrode.

FIG. 16 is a cross-sectional view of a light emitting apparatus showing a second configuration example of the electrode.

FIG. 17 is a schematic configuration diagram of a projector according to a fifth embodiment.

FIG. 18 is a schematic configuration diagram of a projector according to a sixth embodiment.

FIG. 19 is a perspective view showing a first example of a light guide.

FIG. 20 is a perspective view showing a second example of the light guide.

### DESCRIPTION OF EXEMPLARY EMBODIMENTS

### First Embodiment

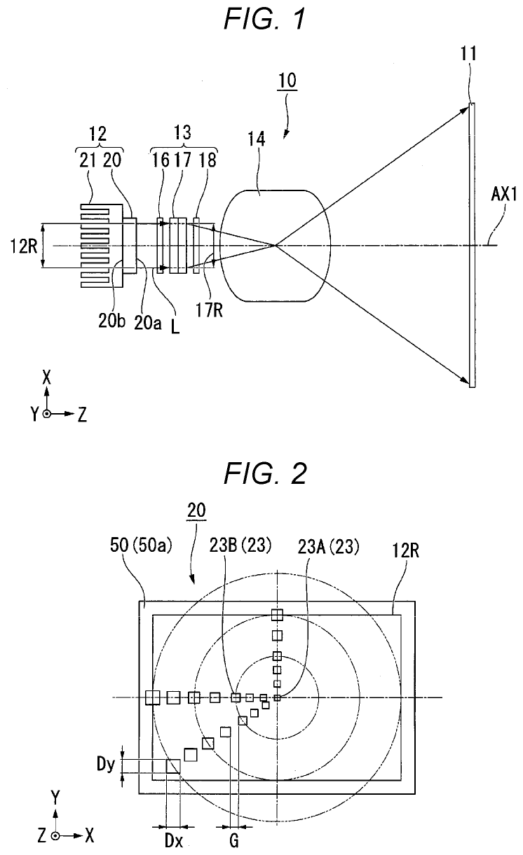

A first embodiment of the present disclosure will be described below with reference to FIGS. 1 to 9.

FIG. 1 is a schematic configuration diagram of a projector according to the present embodiment.

In the following drawings, components are drawn at different dimensional scales in some cases for clarity of each of the components.

A projector 10 according to the present embodiment is a projection-type image display apparatus that projects an image on a screen 11, as shown in FIG. 1. The projector 10 includes a light emitting apparatus 12, a light modulating apparatus 13, and a projection optical apparatus 14. The configuration of the light emitting apparatus 12 will be described later in detail.

An axis that coincides with a normal passing through the center of a light emission region 12R of the light emitting apparatus 12 and serves an optical axis along which the chief ray of a light flux L emitted from the light emission region 12R is hereinafter referred to as an optical axis AX1. Each of the apparatuses described above will be described below by using an XYZ orthogonal coordinate system. In the description, an axis X is an axis parallel to the long edges of the light emission region 12R, which has a rectangular planar shape when viewed along the optical axis AX1, an axis Y is an axis parallel to the short edges of the light emission region, and an axis Z is the axis perpendicular to the axes X and Y. The axis Z is parallel to the optical axis AX1.

The light modulating apparatus 13 modulates the light flux L emitted from the light emitting apparatus 12 in accordance with image information to produce image light. The light modulating apparatus 13 includes a light-incident-side polarizer 16, a liquid crystal display device 17, and a light-exiting-side polarizer 18. When viewed along the axis Z, an image formation region 17R of the liquid crystal display device 17 has a rectangular planar shape. The light emission region 12R of light emitting apparatus 12 has a rectangular planar shape, as described above, and the planar shape of the image formation region 17R is similar to the planar shape of the light emission region 12R. The area of the light emission region 12R is equal to or slightly greater than the area of the image formation region 17R.

The projection optical apparatus 14 projects the image light emitted from the light modulating apparatus 13 on a projection receiving surfaces, such as the screen 11. The projection optical apparatus 14 is formed of one or more projection lenses.

The light emitting apparatus 12 will be described below.

The light emitting apparatus 12 includes a light emitter 20 and a heat sink 21, as shown in FIG. 1. The light emitter 20 has a first surface 20a and a second surface 20b and emits the light flux L via the first surface 20a. The heat sink 21 is provided on the second surface 20b of the light emitter 20 to dissipate heat generated in the light emitter 20.

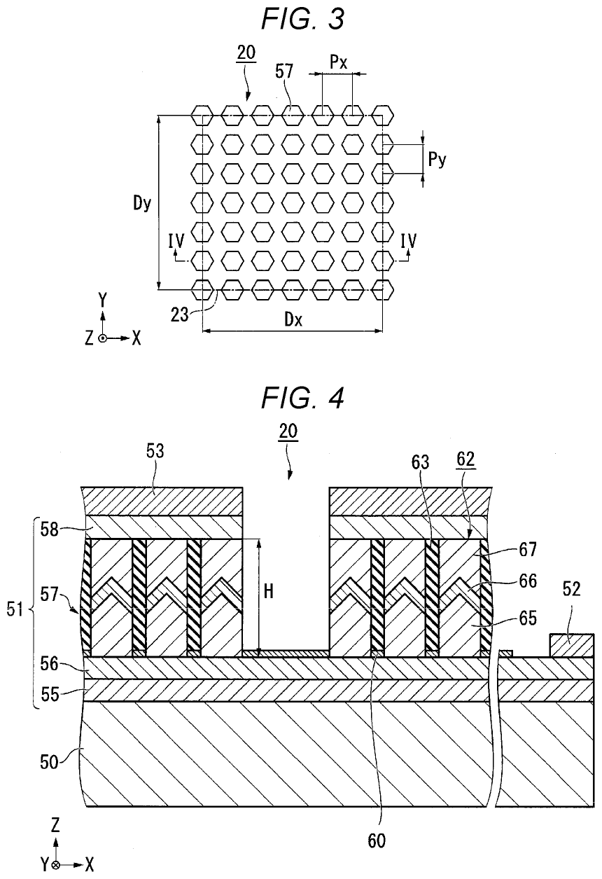

FIG. 2 is a plan view showing a schematic configuration of the light emitter 20. FIG. 3 is a plan view of a resonator 23. FIG. 4 is a cross-sectional view of the resonator 23 taken along the line IV-IV in FIG. 3. FIG. 2 shows only part of the resonators 23 provided in the light emission region 12R and does not show the other resonator 23 for ease of illustration.

The light emitter 20 includes a substrate 50 (base), a laminate 51, a first electrode 52, and second electrodes 53, as shown in FIG. 4. The laminate 51 includes a reflection layer 55, a buffer layer 56, photonic crystal structures 57, and third semiconductor layers 58.

The substrate 50 is formed, for example, of a silicon (Si) substrate, a gallium nitride (GaN) substrate, or a sapphire substrate.

The reflection layer 55 is provided on the substrate 50. The reflection layer 55 is formed, for example, of a distribution Bragg reflector (DBR) layer. The reflection layer 55 is formed, for example, of a laminate in which an AlGaN layer and a GaN layer are alternately layered on each other or an AlInN layer and a GaN layer are alternately layered on each other. The reflection layer 55 reflects light produced by light emitting layers 66, which will be described later, of the photonic crystal structures 57 toward the second electrodes 53.

In the present specification, the directions of the axis Z, which is the lamination direction of the laminate 51, are defined with respect to the light emitting layers 66 as follows: The direction from the light emitting layers 66 toward second semiconductor layers 67 is “upper;” and the direction from the light emitting layers 66 toward first semiconductor layers 65 is “lower.” The “lamination direction of the laminate 51” is the direction in which the first semiconductor layers 65 face the light emitting layers 66 and is hereinafter simply referred to as the “lamination direction” in some cases.

The buffer layer 56 is provided on the reflection layer 55. The buffer layer 56 is made of a semiconductor material and is formed, for example, of an n-type GaN layer into which Si has been doped. In the example shown in FIG. 4, a mask layer 60, grows a film that forms columnar sections 62 in the process of manufacturing the light emitter 20, which will be described later, is provided on the buffer layer 56. The mask layer 60 is formed, for example, of a silicon oxide layer or a silicon nitride layer.

The photonic crystal structures 57 are each a columnar structure provided on the buffer layer 56. The photonic crystal structures 57 include a plurality of columnar sections 62 and a plurality of light propagation layers 63. The photonic crystal structures 57 can provide a photonic crystal effect, which causes the light emitted by the light emitting layers 66 to be confined in the in-plane directions of the substrate 50 and exit in the lamination direction. The “in-plane directions of the substrate 50” are directions along a plane perpendicular to the lamination direction.

The photonic crystal structures 57 each have, for example, a polygonal, circular, or elliptical planar shape. In the present embodiment, the photonic crystal structures 57 each have a regular hexagonal planar shape, as shown in FIG. 3. The photonic crystal structures 57 each have a diameter of the order of nanometers, specifically, a diameter greater than or equal to 10 nm but smaller than or equal to 500 nm. The columnar sections 62 are nano-structures that form the photonic crystal structures 57, as shown in FIG. 4. The dimension of the photonic crystal structures 57, what is called a height H of the photonic crystal structures 57 is, for example, greater than or equal to 1 μm but smaller than or equal to 5 μm.

The “diameter of each of the photonic crystal structures 57” is defined as follows: In a case where the photonic crystal structures 57 have a circular planar shape, the diameter is the diameter of the circle; and when the photonic crystal structures 57 have a non-circular planar shape, the diameter is the diameter of a minimum inclusion circle of the non-circular shape. For example, when the photonic crystal structures 57 have a polygonal planar shape, the diameter is the diameter of the minimum circle containing the polygon therein, and when the photonic crystal structures 57 have an elliptical planar shape, the diameter is the diameter of the minimum circle containing the ellipse therein.

The “center of each of the photonic crystal structures 57” is defined as follows: In the case where the photonic crystal structures 57 have a circular planar shape, the center is the center of the circle; and when the photonic crystal structures 57 have a non-circular planar shape, the center is the center of the minimum inclusion circle of the non-circular shape. For example, when the photonic crystal structures 57 have a polygonal planar shape, the center of each of the photonic crystal structures 57 is the center of the minimum circle containing the polygon therein, and when the photonic crystal structures 57 have an elliptical planar shape, the center of each of the photonic crystal structures 57 is the center of the minimum circle containing the ellipse therein.

The plurality of photonic crystal structures 57 are arranged in the form of a square lattice on the buffer layer 56, as shown in FIG. 3. The intervals Px and Py between adjacent two photonic crystal structures 57 are, for example, greater than or equal to 1 nm but smaller than or equal to 500 nm. In the present embodiment, the interval Px in the direction of the axis X and the interval Py in the direction of the axis Y are equal to each other. As described above, the plurality of photonic crystal structures 57 are periodically arranged at the predetermined intervals Px and Py along the directions of the axes X and Y perpendicular to each other. The interval Px in the direction of the axis X is the distance between the centers of photonic crystal structures 57 adjacent to each other in the direction of the axis X. The interval Py in the direction of the axis Y is the distance between the centers of photonic crystal structures 57 adjacent to each other in the direction of the axis Y. The plurality of photonic crystal structures 57 are not necessarily arranged in the form of a square lattice and may instead be arranged, for example, in the form of an oblong lattice or a triangular lattice.

The columnar sections 62 each include the first semiconductor layer 65, the light emitting layer 66, and the second semiconductor layer 67, as shown in FIG. 4.

The first semiconductor layers 65 are provided on the buffer layer 56. The first semiconductor layers 65 are each formed, for example, of an n-type GaN layer into which Si has been doped.

The light emitting layers 66 are provided on the first semiconductor layers 65. The light emitting layers 66 are provided between the first semiconductor layers 65 and the second semiconductor layers 67. The light emitting layers 66 each have a quantum well structure formed, for example, of a GaN layer and an InGaN layer. The light emitting layers 66 produce light when current is injected thereinto via the first semiconductor layer 65 and the second semiconductor layer 67.

The second semiconductor layers 67 are provided on the light emitting layers 66. The second semiconductor layers 67 are layers different from the first semiconductor layers 65 in terms of conductivity type. The second semiconductor layers 67 are each, for example, a p-type GaN layer into which Mg has been doped. The first semiconductor layer 65 and the second semiconductor layer 67 function as cladding layers having the function of confining the light in the light emitting layers 66.

The light propagation layers 63 are provided between adjacent columnar sections 62. In the example shown in FIG. 4, the light propagation layers 63 are provided on the mask layer 60. The refractive index of the light propagation layers 63 is lower than the refractive index of the light emitting layers 66. The light propagation layers 63 are each formed, for example, of a silicon oxide layer, an aluminum oxide layer, or a titanium oxide layer. The light produced in the light emitting layers 66 propagates through the light propagation layers 63.

The resonators 23 are each formed of a plurality of photonic crystal structures 57 arranged in the form of a square lattice, as shown in FIG. 3. A plurality of resonators 23 are so disposed on a first surface 50a of the substrate 50 as to be separate from each other, as shown in FIG. 2. That is, no photonic crystal structure 57 is provided between adjacent resonators 23. The plurality of resonators 23 form the light emission region 12R, which emits light that the periodic structure of each of the photonic crystal structures 57 causes to resonate.

In adjacent two resonators 23, the light that resonates in one of the resonators 23 does not reach the other resonator 23. A distance G between resonators 23 adjacent to each other is greater than the wavelength of the light produced in the light emitting layers 66. The thus configured resonators 23 allow the light that resonates in one of resonators 23 adjacent to each other not to reach the other resonator 23.

Light absorbers that absorb light may be provided between adjacent resonators 23. The light absorbers are made of a material having a bandgap narrower than the bandgap corresponding to the light that resonates in the resonators 23. Materials of this type may include InGaN and InN. The light absorbers are each formed, for example, of a columnar or wall-shaped crystal provided between adjacent resonators 23. The light absorbers allow the light that resonates in one of resonators 23 adjacent to each other not to reach the other resonator 23.

Instead, light reflectors that reflect light may be provided between adjacent resonators 23. For example, the light reflectors can be formed by providing columnar structures between adjacent resonators 23, the columnar structures arranged at intervals smaller than the intervals at which the photonic crystal structures 57, which form each of the resonators 23, are arranged or the columnar structures having a diameter smaller than the diameter of the photonic crystal structures 57. The thus configured light absorbers allow the light that resonates in one of resonators 23 adjacent to each other not to reach the other resonator 23.

In the light emitting apparatus 12, a laminate of each of the p-type second semiconductor layers 67, the light emitting layers 66 into which no impurity has been doped, and the n-type first semiconductor layers 65 forms a pin diode. The bandgaps of the first semiconductor layer 65 and the second semiconductor layer 67 is wider than the bandgap of the light emitting layer 66. When forward bias voltage for the pin diode is applied to the gap between the first electrode 52 and the second electrodes 53, current is injected into the light emitting layers 66, resulting in electron-hole recombination in the light emitting layers 66, followed by the light emission.

The first semiconductor layers 65 and the second semiconductor layers 67 cause the light produced in the light emitting layers 66 to propagate through the light propagation layers 63 in the in-plane directions of the substrate 50. In this process, the light forms a standing wave due to the photonic crystal effect provided by the photonic crystal structures 57 and is confined in the in-plane directions of the substrate 50. The confined light receives gain in the light emitting layers 66, resulting in laser oscillation. That is, the photonic crystal structures 57 cause the light produced in the light emitting layers 66 to resonate in the in-plane directions of the substrate 50, resulting in laser oscillation. Specifically, the light produced in the light emitting layers 66 resonates in the in-plane directions of the substrate 50 in the resonators 23 each formed of the plurality of photonic crystal structures 57, resulting in laser oscillation. Thereafter, ±1st-order diffracted light produced by the resonance travels as laser light in the lamination direction (direction of axis Z).

Out of the laser light having traveled in the lamination direction, the laser light having traveled toward the reflection layer 55 is reflected off the reflection layer 55 and travels toward the second electrodes 53. The light emitting apparatus 12 can thus emit the light via the second electrodes 53.

The third semiconductor layers 58 are provided on the photonic crystal structures 57. The third semiconductor layers 58 are each formed, for example, of a p-type GaN layer into which Mg has been doped.

The first electrode 52 is provided on the buffer layer 56 on a side of the photonic crystal structures 57. The first electrode 52 may be in ohmic contact with the buffer layer 56. In the example shown in FIG. 3, the first electrode 52 is electrically coupled to the first semiconductor layers 65 via the buffer layer 56. The first electrode 52 is one of the electrodes via which current is injected into the light emitting layers 66. The first electrode 52 is, for example, a laminate film of a Ti layer, an Al layer, and an Au layer layered in this order from the side facing the buffer layer 56.

The second electrodes 53 are provided on the third semiconductor layers 58. The second electrodes 53 may be in ohmic contact with the third semiconductor layers 58. The second electrodes 53 are electrically coupled to the second semiconductor layers 67. In the example shown in FIG. 4, the second electrodes 53 are electrically coupled to the second semiconductor layers 67 via the third semiconductor layers 58. The second electrodes 53 are the other one of the electrodes via which current is injected into the light emitting layers 66. The second electrodes 53 are made, for example, of ITO (indium tin oxide). The second electrode 53 provided at one of adjacent photonic crystal structures 57 is electrically coupled via wiring that is not shown to the second electrode 53 provided at the other photonic crystal structure 57.

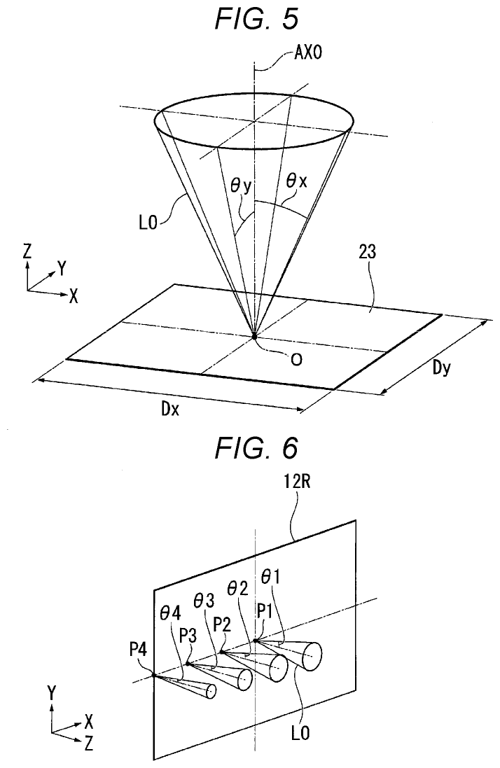

FIG. 5 shows the light orientation angle of light L0 emitted from each of the resonators 23.

An axis-X-direction length Dx of the resonator 23 is equal to an axis-Y-direction length Dy of the resonator 23 in the plan view, as shown in FIG. 3. When the lengths Dx and Dy of the resonator 23 is equal to each other as described above, an axis-X-direction light orientation angle θx of the light L0 emitted from the resonator 23 is equal to an axis-Y-direction light orientation angle θy of the light L0, as shown in FIG. 5. Conversely, comparison between the axis-X-direction light orientation angle θx of the light L0 emitted from the resonator 23 and the axis-Y-direction light orientation angle θy of the light L0 allows checking of whether or not the lengths Dx and Dy are equal to each other. When the resonators 23 have a rotationally symmetric planar shape, such as a square or a regular hexagonal shape, the light orientation angle of the light L0 emitted from each of the resonators 23 is rotationally symmetric with respect to an optical axis AX0. The light orientation angle is defined as the angle between the outermost light ray emitted from one light emission point O and a normal passing through the light emission point O.

In the plan view, the outer shape of each of the resonators 23 is a square corresponding to the figure surrounded by the straight lines that connect the centers of the photonic crystal structures 57 located at the outermost circumference out of the plurality of photonic crystal structures 57 that form the resonator 23, as shown in FIG. 3. In each of the resonator 23, the light emitted from the light emitting layer 66 resonates in each of the directions of the axes X and Y along which the plurality of photonic crystal structures 57 are arranged at the fixed intervals in the resonator 23. That is, the light L0 resonates in two resonance directions.

The axis-X-direction resonant length of each of the resonators 23 corresponds to the length Dx of the straight line that connects the centers of the plurality of photonic crystal structures 57 arranged in a row in the direction of the axis X. Similarly, the axis-Y-direction resonant length of the resonator 23 corresponds to the length Dy of the straight line that connects the centers of the plurality of photonic crystal structures 57 arranged in a row in the direction of the axis Y. In the present embodiment, since the resonators 23 each have a square outer shape, the axis-X-direction resonance length of each of the resonators 23 is equal to the axis-Y-direction resonance length of the resonator 23. The axis-X-direction length Dx and the axis-Y-direction length Dy of each of the resonators 23 are hereinafter collectively referred to as the size of the resonator 23 in some cases.

In the light emission region 12R, the sizes Dx and Dy of the plurality of resonators 23 gradually increase with distance from a central portion of the light emission region 12R toward a peripheral portion thereof, as shown in FIG. 2. In other words, the axis-X-direction resonance length and the axis-Y-direction resonance length of the plurality of resonators 23 gradually increase with distance from the central portion of the light emission region 12R toward the peripheral portion thereof. The diameter and height of the photonic crystal structures 57 provided in each of the resonators 23, the intervals at which the photonic crystal structures 57 are arranged, the arrangement of the photonic crystal structures 57, and other parameters thereof are the same in all the resonators 23.

Now assume that an arbitrary resonator 23 located in a position close to the central portion of the light emission region 12R is called a first resonator 23A, and that an arbitrary resonator 23 located in a position farther from the central portion of the light emission region 12R than the first resonator 23A is called a second resonator 23B. That is, the plurality of resonators 23 include the first resonator 23A and the second resonator 23B.

For example, it is assumed in FIG. 2 that the resonator 23 located at the center of the light emission region 12R is the first resonator 23A, and that the fourth resonator 23 counted from the resonator located at the center of the light emission region 12R is the second resonator 23B. Under the definition described above, the distance from the center of the light emission region 12R to the second resonator 23B is longer than the distance from the center of the light emission region 12R to the first resonator 23A, and the resonance length of the second resonator 23B is longer than the resonance length of the first resonator 23A.

In the present embodiment, the plurality of resonators 23 located at the same distance from the center of the light emission region 12R have the same resonance length. In FIG. 2, a curve that connects the plurality of resonators 23 having the same resonance length to each other is shown in the form of a circle drawn with a two-dot chain line. There are a large number of such circles, and FIG. 2 shows only three such circles.

In the present embodiment, a plurality of resonators 23 having the same resonance length are arranged concentrically around the center of the light emission region 12R. That is, the ratio of the amount of change in the resonance length of a resonator 23 to the amount of change in the distance from the center of the light emission region 12R to the resonator 23 is fixed in all the directions viewed from the center of the light emission region 12R. A plurality of resonators 23 having the same resonance length may instead be arranged, for example, in the form of concentric rectangles or concentric ellipses around the center of the light emission region 12R. That is, the ratio of the amount of change in the resonance length of a resonator 23 to the amount of change in the distance from the center of the light emission region 12R to the resonator 23 may vary among the directions viewed from the center of the light emission region 12R.

Due to a photonic crystal effect, the size, that is, the resonance length of a resonator 23 affects the light orientation angle of the light L0 emitted from the resonator 23. Specifically, the greater the size of a resonator 23, the smaller the light orientation angle of the light L0 emitted from the resonator 23, whereas the smaller the size of a resonator 23, the greater the light orientation angle of the light L0 emitted from the resonator 23.

FIG. 6 shows the light orientation angles of the light L0 emitted from a plurality of resonators 23 located in positions P1, P2, P3, and P4 different from one another in the light emission region 12R. FIG. 6 shows only the light L0 emitted from the resonators 23 located in the four positions P1, P2, P3, and P4 arranged along the direction of the axis X out of the large number of resonators 23 present in the light emission region 12R.

In the present embodiment, the size, that is, the resonance length of the resonators 23 gradually increases with distance from the center of the light emission region 12R toward the periphery thereof, as described above. Let θ1 be the light orientation angle of the light L0 emitted from the resonator 23 in the position P1, θ2 be the light orientation angle of the light L0 emitted from the resonator 23 in the position P2, θ3 be the light orientation angle of the light L0 emitted from the resonator 23 in the position P3, and θ4 be the light orientation angle of the light L0 emitted from the resonator 23 in the position P4, and the magnitudes of the light orientation angles θ1 to θ4 are expressed as follows: θ1>θ2>θ3>θ4, as shown in FIG. 6. That is, the light orientation angles of the light L0 emitted from the resonators 23 gradually decrease with distance from the center of the light emission region 12R toward the periphery thereof.

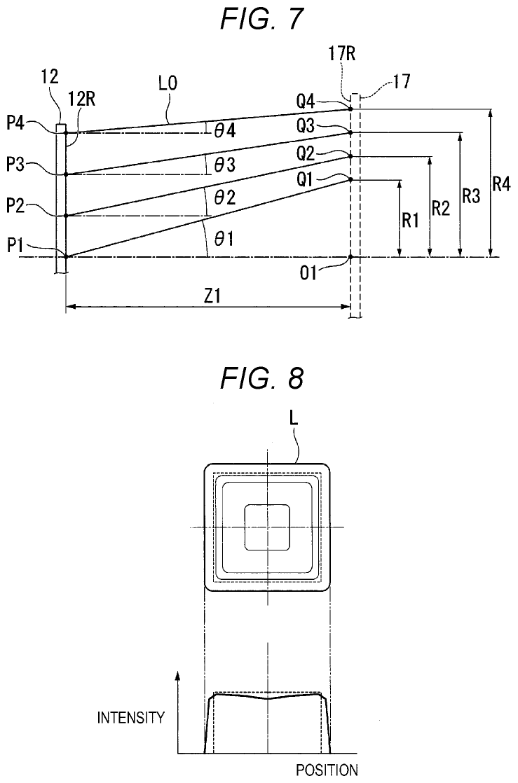

FIG. 7 shows the positions where the light L0 emitted from the positions P1, P2, P3, and P4 in FIG. 6 reaches the image formation region 17R of the liquid crystal display device 17.

The light flux L emitted from the light emitting apparatus 12 travels via the light-incident-side polarizer 16 and is incident on the image formation region 17R of the liquid crystal display device 17 disposed in a position separate from the light emitting apparatus 12 by a distance Z1. Let Q1, Q2, Q3, and Q4 be the positions where the light L0 emitted from the resonators 23 in the positions P1, P2, P3, and P4 reaches the image formation region 17R, and let R1, R2, R3, and R4 be the distances from a center O1 of the image formation region 17R to the positions Q1, Q2, Q3, and Q4, and the magnitudes of the distances are desirably expressed by R1<R2<R3<R4. In other words, it is desirable that the position where the light L0 emitted from a resonator 23 close to the center of the light emission region 12R reaches is not beyond but is within the position where the light L0 emitted from a resonator 23 located in a position far from the center of the light emission region 12R.

Now, consider a light emitting apparatus according to Comparative Example in which the light emission region has a plurality of resonators having the same size (resonance length). It is assumed that the light emission region has a square planar shape.

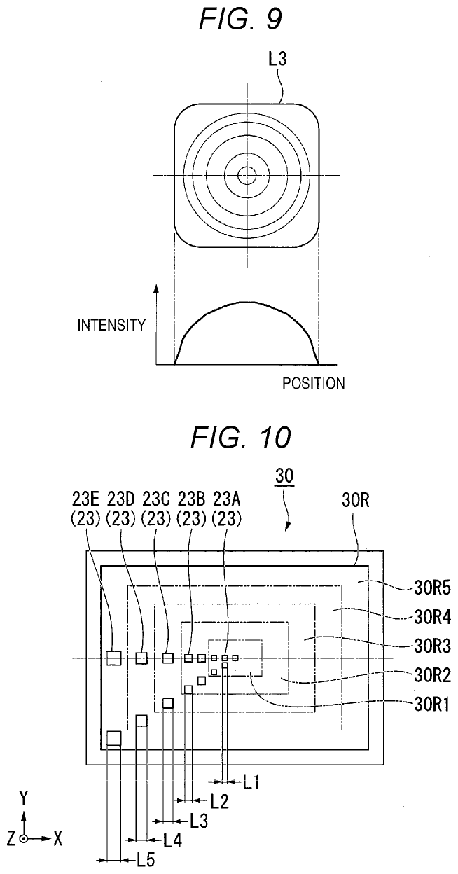

FIG. 9 shows the cross-sectional shape perpendicular to the chief ray of a light flux L3 and the intensity distribution of the light flux L3 in an illumination receiving region of the light emitting apparatus according to Comparative Example. The upper portion of FIG. 9 shows the cross-sectional shape of the light flux L3, and the lower portion of FIG. 9 shows the intensity distribution of the light flux. The upper portion of FIG. 9 further shows intensity contour lines (iso-intensity lines) in addition to the cross-sectional shape of the light flux L3.

In the light emitting apparatus according to Comparative Example, the cross-sectional shape of the light flux L3 emitted from the square light emission region changes from the square to a shape having rounded corners, as shown in FIG. 9. Further, the intensity distribution of the light flux L3 is so shaped that the intensity is high at the center of the illumination receiving region and low at the periphery thereof, and that the intensity greatly varies depending on the position in the illumination receiving region.

In contrast, FIG. 8 shows the cross-sectional shape perpendicular to the chief ray of the light flux L and the intensity distribution of the light flux Lin the illumination receiving region in the light emitting apparatus 12 according to the present embodiment. The upper portion of FIG. 8 shows the cross-sectional shape of the light flux L, and the lower portion of FIG. 8 shows the intensity distribution of the light flux L. The upper portion of FIG. 8 further shows intensity contour lines (iso-intensity lines) in addition to the cross-sectional shape of the light flux. The broken lines in the upper and lower portions of FIG. 8 represent the cross-sectional shape and the intensity distribution of the light flux L immediately after the light flux Lis emitted from the light emitting apparatus 12. It is assumed in the description that the light emission region 12R has a square planar shape for comparison with Comparative Example.

In the light emitting apparatus 12 according to the present embodiment, the cross-sectional shape of the light flux L emitted from the light emission region 12R has corners that are not greatly rounded, unlike in Comparative Example, but does not greatly differ from the square, as shown in FIG. 8. Further, the light emitted from the central portion of the light emission region 12R greatly spreads, but the light emitted from the peripheral portion of the light emission region 12R does not greatly spread. The intensity distribution of the light flux L emitted from the light emission region 12R is therefore so shaped that the intensity is slightly higher at the peripheral portion of the light emission region 12R than that in the central portion, but that a substantially uniform intensity distribution is provided irrespective of the position in the illumination receiving region. As described above, the cross-sectional shape and the intensity distribution of the light flux L immediately after the light flux L is emitted from the light emitting apparatus 12 are sufficiently maintained even in the illumination receiving region.

As described above, the light emitting apparatus 12 according to the present embodiment, in which the plurality of resonators 23 have different resonance lengths so that the light orientation angle varies in accordance with the position in the light emission region 12R, can control the cross-sectional shape and the intensity distribution of the light flux L in the illumination receiving region separate from the light emitting apparatus 12. In the present embodiment, in particular, since the light orientation angle of the light emitted from a resonator 23 located at the peripheral portion of the light emission region 12R is smaller than the light orientation angle of the light emitted from a resonator 23 located in the central portion of the light emission region 12R, the cross-sectional shape of the light flux L immediately after the light flux L is emitted from the light emitting apparatus 12 can be sufficiently maintained even in the image formation region 17R of the liquid crystal display device 17 separate from the light emitting apparatus 12.

The thus configured light emitting apparatus 12 according to the present embodiment, which allows the cross-sectional shape of the light flux L emitted therefrom to be substantially match with the shape of the image formation region 17R, can efficiently illuminate the light modulating apparatus 13. It is noted that the cross-sectional shape of the light flux L changes depending on the light orientation angle and the distribution of the light flux L emitted from the light emitting apparatus 12, the intensity and the distribution of the light flux L, the distance from the light emitting apparatus 12, and other factors.

Since the projector 10 according to the present embodiment includes the light emitting apparatus 12 that provides the effect described above, the light can be used efficiently, and the size of the projector 10 can be reduced.

### Second Embodiment

A second embodiment of the present disclosure will be described below with reference to FIG. 10.

The basic configuration of the light emitting apparatus according to the second embodiment is the same as that in the first embodiment, and the second embodiment differs from the first embodiment in terms of the configuration of the plurality of resonators. No description of the entire light emitting apparatus will therefore be made.

FIG. 10 is a plan view of the light emitting apparatus according to the second embodiment.

In FIG. 10, the components common to those in FIG. 2 used in the description of the first embodiment have the same reference characters and will not be described.

In a light emitting apparatus 30 according to the present embodiment, a light emission region 30R is divided into a plurality of rectangular divided regions concentric around the center of the light emission region 30R, as shown in FIG. 10. In the present embodiment, the plurality of divided regions include five divided regions, a first divided region 30R1, a second divided region 30R2, a third divided region 30R3, a fourth divided region 30R4, and a fifth divided region 30R5, sequentially arranged from the center of the light emission region 30R. The “divided regions” in the present disclosure do not mean that a component of the light emitting apparatus 30 is physically divided but means separate regions in the light emission region 30R in each of which a plurality of resonators 23 having the same size are disposed, as will be described later.

The plurality of resonators 23 include a plurality of first resonators 23A, a plurality of second resonators 23B, a plurality of third resonators 23C, a plurality of fourth resonators 23D, and a plurality of fifth resonators 23E. The plurality of first resonators 23A are provided in the first divided region 30R1. The plurality of second resonators 23B are provided in the second divided region 30R2. The plurality of third resonators 23C are provided in the third divided region 30R3. The plurality of fourth resonators 23D are provided in the fourth divided region 30R4. The plurality of fifth resonators 23E are provided in the fifth divided region 30R5.

Also in the present embodiment, in which the resonators 23 each have a square planar shape, the axis-X-direction length Dx of each of the resonators 23 is equal to the axis-Y-direction length Dy of the resonator 23, as in the first embodiment. The axis-X-direction length Dx and the axis-Y-direction length Dy of each of the resonators 23 are therefore collectively referred to as the size of the resonator 23 in the description. Let L1 be the size of the first resonators 23A, L2 be the size of the second resonators 23B, L3 be the size of the third resonators 23C, L4 be the size of the fourth resonators 23D, and L5 be the size of the fifth resonators 23E.

The size of the plurality of resonators 23, that is, the resonance length increases with distance from the center of the light emission region 30R toward the periphery thereof. The size of the resonators 23 is expressed as follows: L1<L2<L3<L4<L5. The plurality of first resonators 23A in the first divided region 30R1 have the same size, that is, resonance length. The plurality of second resonators 23B in the second divided region 30R2 have the same size, that is, resonance length. The plurality of third resonators 23C in the third divided region 30R3 have the same size, that is, resonance length. The plurality of fourth resonators 23D in the fourth divided region 30R4 have the same size, that is, resonance length. The plurality of fifth resonators 23E in the fifth divided region 30R5 have the same size, that is, resonance length.

In the light emitting apparatus 12 according to the first embodiment, the light emission region 12R is not divided, and the size, that is, the resonance length of the plurality of resonators 23 continuously increases with distance from the central portion of the light emission region 12R toward the peripheral portion thereof. In contrast, in the light emitting apparatus 30 according to the present embodiment, the light emission region 30R is divided into the plurality of divided regions 30R1, 30R2, 30R3, 30R4, and 30R5, and the closer a divided region to the periphery of the light emission region 30R, the greater the size of the resonators 23 in the divided region, that is, the longer the resonance length, and the plurality of resonators 23 in each of the divided regions have the same size, that is, resonance length. Simply speaking, in the light emitting apparatus 30 according to the present embodiment, the size, that is, the resonance length of the plurality of resonators 23 increases stepwise with distance from the central portion of the light emission region 30R toward the peripheral portion thereof.

The other configurations of the light emitting apparatus 30 are the same as those in the first embodiment.

The light emitting apparatus 30 according to the present embodiment, which allows the shape of the light flux to substantially match with the shape of the image formation region, also provides the same effect provided by the first embodiment, for example, the light modulating apparatus can be efficiently illuminated.

Further, in the present embodiment, since the separate divided regions 30R1, 30R2, 30R3, 30R4, and 30R5 are each formed of the resonators 23 having the same size, the plurality of resonators 23 are likely to be arranged at a high density in the light emission region 30R, as compared with the light emitting apparatus 12 according to the first embodiment. The packing ratio of the resonators 23 per light emission area can thus be increased, whereby the light emission density can be increased.

In the present embodiment, the light emission region 30R is divided into the five divided regions 30R1, 30R2, 30R3, 30R4, and 30R5 and may be divided into a larger number of divided regions. The larger the number of divided regions, the closer the characteristics of the light emitting apparatus 30 to those in the first embodiment, in which the resonance length continuously changes.

### Variation

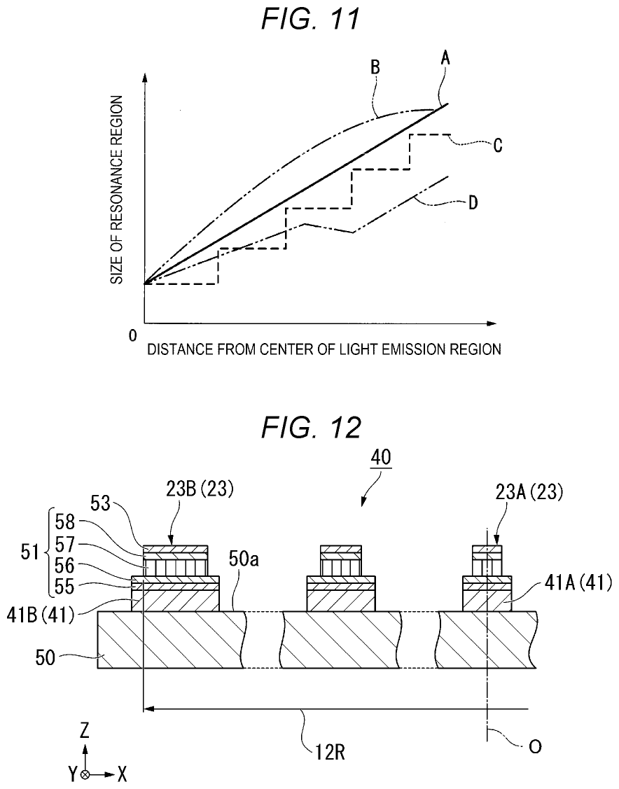

FIG. 11 shows the relationship between the distance from the center of the light emission region and the size of the resonators. In FIG. 11, the horizontal axis represents the distance from the center of the light emission region, and the vertical axis represents the size, that is, the resonance length of the resonators.

In FIG. 11, the graphs labeled with reference characters A and B correspond to the light emitting apparatus 12 according to the first embodiment, and the size of the resonators continuously changes in accordance with a change in the distance from the center of the light emission region. In this case, the ratio of the amount of change in the size of the resonators to the amount of change in the distance from the center of the light emission region may be fixed irrespective of the distance from the center of the light emission region, as indicated by the graph labeled with the reference character A, or may change in accordance with the distance from the center of the light emission region, as indicated by the graph labeled with the reference character B.

In FIG. 11, the graph labeled with a reference character C corresponds to the light emitting apparatus 30 according to the second embodiment, and the size of the resonators changes stepwise in accordance with the distance from the center of the light emission region. Further, the size of the resonators may locally decrease as the positions of the resonators are shifted away from the central portion of the light emission region, as indicated by a graph labeled with a reference character D. As described above, the size of the resonators may not necessarily monotonously increase in accordance with an increase in the distance from the center of the light emission region, and the size of the resonators closer to the periphery of the light emission region only needs to be greater than the size of the resonators closer to the center of the light emission region when the light emission region is taken as a whole.

### Third Embodiment

A third embodiment of the present disclosure will be described below with reference to FIG. 12.

The basic configuration of a light emitting apparatus according to the third embodiment is the same as that in the first embodiment but differs from the first embodiment in terms of the configuration of the base. No description will therefore be made of the entire light emitting apparatus.

FIG. 12 is a cross-sectional view of a light emitting apparatus 40 according to the third embodiment.

In FIG. 12, the components common to those in the figures used in the description of the first embodiment have the same reference characters and will not be described.

The light emitting apparatus 40 according to the present embodiment includes the substrate 50 (base), intermediate substrates 41 (intermediate bases), the laminate 51, the first electrode (not shown), and the second electrodes 53, as shown in FIG. 12. The laminate 51 includes the reflection layers 55, the buffer layers 56, the photonic crystal structures 57 (columnar structures), and the third semiconductor layers 58. The detailed configuration of the photonic crystal structures 57 is the same as that of the photonic crystal structures 57 in the first embodiment shown in FIG. 4. Although not shown, wiring is formed in each of the substrate 50 and the intermediate substrates 41, and the second electrodes 53 are electrically coupled to the wiring in the substrate 50 via the wiring formed in the intermediate substrates 41. The first electrode is electrically coupled to the wiring in the substrate 50, for example, via the wiring formed in the intermediate substrates 41. The first electrode may instead be electrically coupled to the wiring in the substrate 50 via the rear surfaces of the intermediate substrates 41.

In the present embodiment, the plurality of resonators 23 are provided on the first surface 50a of the substrate 50 via the plurality of intermediate substrates 41. That is, the plurality of intermediate substrates 41 are provided on the first surface 50a of the substrate 50, and the plurality of resonators 23 are each provided on the corresponding one of the plurality of intermediate substrates 41. The plurality of intermediate substrates 41 include a first intermediate substrate 41A (first intermediate base) and second intermediate substrates 41B (second intermediate bases).

It is assumed as in the first embodiment that the resonator 23 located at the center O of the light emission region 12R is called the first resonator 23A, and that a resonator 23 located in a position separate from the center O of the light emission region 12R is called the second resonator 23B. The distance from the center of the light emission region 12R to the second resonator 23B is longer than the distance from the center of the light emission region 12R to the first resonator 23A, and the resonance length of the second resonator 23B is longer than the resonance length of the first resonator 23A. In the present embodiment, the size, that is, the resonance length of the resonators 23 gradually increases with distance from the center of the light emission region 12R toward the periphery thereof, as shown in FIG. 4, which has been used in the description of the first embodiment.

In the present embodiment, the first resonator 23A is provided on the first intermediate substrate 41A, and the second resonator 23B is provided on the second intermediate substrate 41B. That is, the first resonators 23A and the second resonators 23B are provided on intermediate substrates 41A and 41B different from each other.

The intermediate substrates 41 are made, for example, of silicon (Si), gallium nitride (GaN), sapphire, or any other material. The substrate 50 is made, for example, of silicon (Si), gallium nitride (GaN), sapphire, aluminum nitride (AlN), silicon carbide (SiC), or any other material.

The other configurations of the light emitting apparatus 40 are the same as those in the first embodiment.

The present embodiment, which allows the shape of the light flux to substantially match with the shape of the image formation region, also provides the same effect provided by the first embodiment, that is, the light modulating apparatus can be efficiently illuminated.

Further, according to the configuration of the present embodiment, the steps of manufacturing the light emitting apparatus 40 can be carried out in accordance with a method for forming the resonators 23 on the intermediate substrates 41 and then transferring the resonators 23 along with the intermediate substrates 41 to predetermined positions on the substrate 50. The light emitting apparatus 40 can thus be efficiently manufactured at a high yield.

### Fourth Embodiment

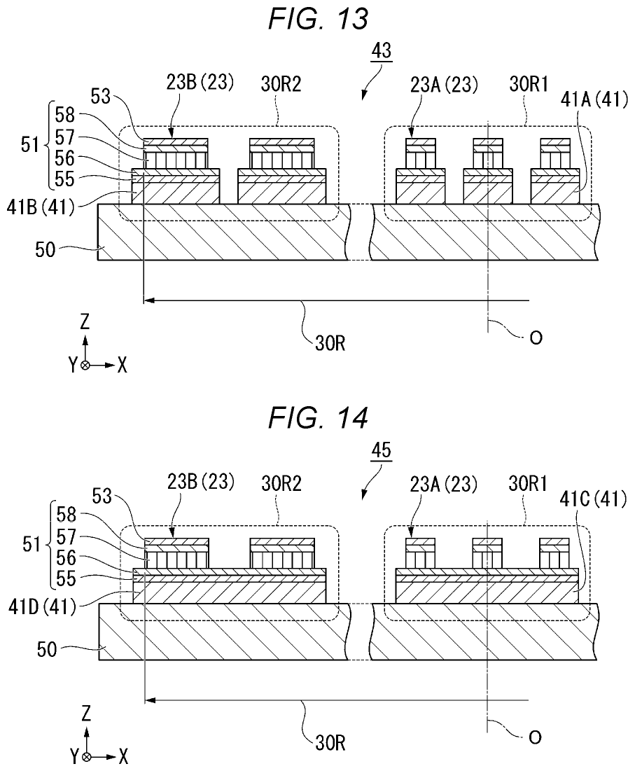

A fourth embodiment of the present disclosure will be described below with reference to FIG. 13.

The basic configuration of a light emitting apparatus according to the fourth embodiment is the same as that in the second embodiment but differs from the second embodiment in terms of the configuration of the base. No description will therefore be made of the entire light emitting apparatus.

FIG. 13 is a cross-sectional view of a light emitting apparatus 43 according to the fourth embodiment.

In FIG. 13, the components common to those in the figures used in the description of the above embodiments have the same reference characters and will not be described.

The plurality of resonators 23 are provided on the first surface 50a of the substrate 50 via the plurality of intermediate substrates 41 also in the light emitting apparatus 43 according to the present embodiment, as shown in FIG. 13, as in the third embodiment. That is, the plurality of intermediate substrates 41 are provided on the first surface 50a of the substrate 50, and the plurality of resonators 23 are each provided on the corresponding one of the plurality of intermediate substrates 41. The plurality of intermediate substrates 41 include the first intermediate substrate 41A (first intermediate base) and the second intermediate substrates 41B (second intermediate bases). Also in the present embodiment, although not shown, wiring is formed in each of the substrate 50 and the plurality of intermediate substrates 41, and the second electrodes 53 are electrically coupled to the wiring in the substrate 50 via the wiring formed in the plurality of intermediate substrates 41. The first electrode is electrically coupled to the wiring in the substrate 50, for example, via the wiring formed in the intermediate substrates 41. The first electrode may instead be electrically coupled to the wiring in the substrate 50 via the rear surfaces of the plurality of intermediate substrates 41.

In the present embodiment, as shown in FIG. 10, as in the second embodiment, the light emission region 30R has the plurality of divided regions 30R1 and 30R2. In the present embodiment, the plurality of divided regions include the first divided region 30R1 and the second divided region 30R2 sequentially arranged from the center O of the light emission region 30R. The plurality of resonators 23 include the plurality of first resonators 23A and the plurality of second resonators 23B. The plurality of first resonators 23A are provided in the first divided region 30R1. The plurality of second resonators 23B are provided in the second divided region 30R2. The size, that is, the resonance length of the plurality of resonators 23 increases stepwise with distance from the central portion of the light emission region 30R toward the peripheral portion thereof.

In the present embodiment, the number of first intermediate substrates 41A provided in the first divided region 30R1 is equal to the number of first resonators 23A. That is, one first resonator 23A is provided on one first intermediate substrate 41A. Similarly, the number of second intermediate substrates 41B provided in the second divided region 30R2 is equal to the number of second resonators 23B. One second resonator 23B is provided on one second intermediate substrate 41B.

The other configurations of the light emitting apparatus 43 are the same as those in the first embodiment.

The present embodiment, which allows the shape of the light flux to substantially match with the shape of the image formation region, also provides the same effect provided by the first embodiment, for example, the light modulating apparatus can be efficiently illuminated. The present embodiment further provides the same effect provided by the third embodiment, that is, the resonators 23 are formed on the intermediate substrates 41, the intermediate substrates 41 are then cut, and the resonators 23 along with the intermediate substrates 41 are transferred to predetermined positions on the substrate 50, whereby the light emitting apparatus 43 can thus be efficiently manufactured at a high yield.

The light emitting apparatus 43 according to the present embodiment may have the configuration of a variation shown below. FIG. 14 is a cross-sectional view of a light emitting apparatus 45 according to the variation.

In the light emitting apparatus 45 according to the variation, the plurality of first resonators 23A are provided on one first intermediate substrate 41C, and the plurality of second resonators 23B are provided on one second intermediate substrate 41D, as shown in FIG. 14. That is, in the light emitting apparatus 45 according to the variation, the plurality of resonators 23 having the same size are provided on one intermediate substrate 41. A gap is provided between adjacent resonators 23 to separate the resonators 23. The second electrodes 53, which are located on the photonic crystal structures 57, are electrically coupled to each other between adjacent resonators 23.

As the configurations of the first and second electrodes, the following two configuration examples may be employed.

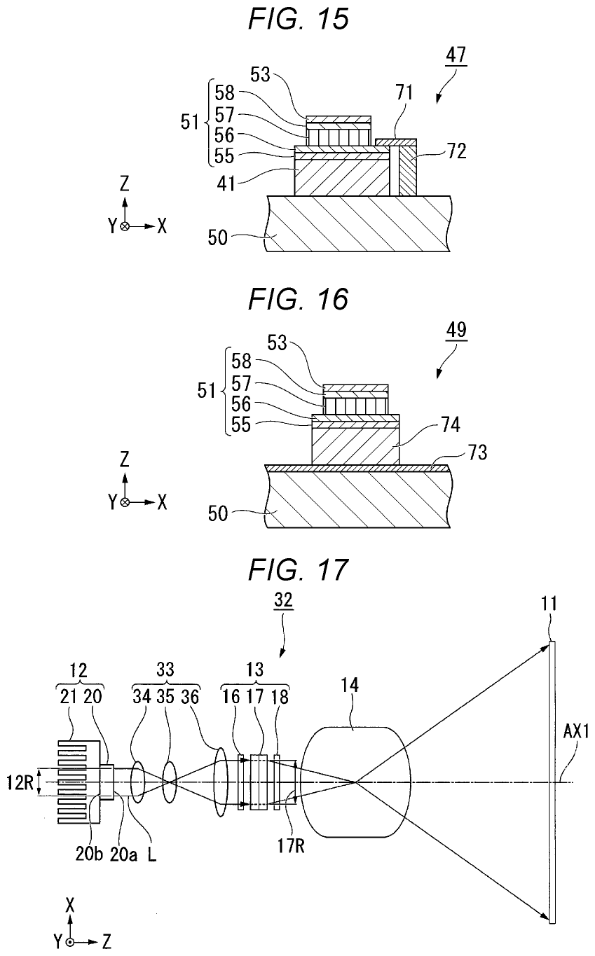

FIG. 15 is a cross-sectional view of a light emitting apparatus 47 showing a first configuration example of the electrodes.

In the light emitting apparatus 47 according to the first configuration example, the second electrode 53 (p electrode) is formed on the upper surface of the photonic crystal structure 57 via the third semiconductor layer 58, as shown in FIG. 15. A first electrode 71 (n electrode) is formed on the intermediate substrate 41 via the reflection layer 55 and the buffer layer 56. The first electrode 71 (n electrode) is electrically coupled to wiring 72 formed on the lateral side of the intermediate substrate 41. Adjacent second electrodes 53 are electrically coupled to each other via wiring that is not shown but is formed, for example, of an ITO layer. The first electrode and the wiring 72 can be coupled to each other, for example, by patterning a metal film in a lift-off method.

FIG. 16 is a cross-sectional view of a light emitting apparatus 49 showing a second configuration example of the electrodes.

The light emitting apparatus 49 according to the second configuration example differs from the light emitting apparatus 47 according to the first configuration example in terms of position of the first electrode (n electrode), as shown in FIG. 16. In the second configuration example, an intermediate substrate 74 is made of an electrically conductive material, for example, n-type GaN to which Si has been doped. The reflection layer 55 is an n-type reflection layer having electrical conductivity and formed of a DBR layer made, for example, of n-type GaN/AlInN to which Si has been doped. The intermediate substrate 74 can thus have the function of the first electrode (n electrode). The buffer layer 56 is formed of an n-type GaN layer to which Si has been doped. The intermediate substrate 74 is disposed on wiring 73 formed on the substrate 50. In the second configuration example, the substrate 50 needs to be an insulating substrate, such as an AlN substrate and an SiC substrate.

In the second configuration example, different from the first configuration example, no wiring 72 coupled to the first electrode needs to be formed along the thickness direction of the intermediate substrate 41. The structure used to mount the intermediate substrate 74 on the substrate 50 and how to mount the intermediate substrate 74 on the substrate 50 can therefore be simplified. The light emitters can be arranged at an increased density, whereby a light emitting apparatus having a high light flux density can be provided.

### Fifth Embodiment

Fifth and sixth embodiments will be described below about other configuration examples of the projector that can use any of the light emitting apparatuses according to the present disclosure.

The basic configuration of the projectors according to the fifth and sixth embodiments is the same as that of the projector according to the first embodiment. Therefore, no description will be made of the basic configuration, and only different portions will be described.

FIG. 17 is a schematic configuration diagram of the projector according to the fifth embodiment.

In FIG. 17, the components common to those in FIG. 1 used in the description of the first embodiment have the same reference characters and will not be described.

A projector 32 according to the fifth embodiment further includes a relay system 33, which is provided between the light emitting apparatus 12 and the light modulating apparatus 13, as shown in FIG. 17. The relay system 33 includes a light-incident-side lens 34, a relay lens 35, and a light-exiting-side lens 36. The light-incident-side lens 34 and the light-exiting-side lens 36 are configured to be optically conjugate with each other. The thus configured relay system 33 transmits the light flux image incident on the light-incident-side lens 34, that is, the intensity distribution of the light flux L to the light-exiting-side lens 36 in such a way that the intensity distribution remains unchanged in terms of size or is enlarged or reduced, and emits the resultant light flux image via the light-exiting-side lens 36. FIG. 17 shows an example of the relay system 33 that enlarges the light flux image and transmits the enlarged light flux image.

The intensity distribution of the light flux L with which the image formation region 17R of the liquid crystal display device 17 is illuminated is therefore substantially the same as the intensity distribution of the light flux L incident on the light-incident-side lens 34. That is, to illuminate the image formation region 17R of the liquid crystal display device 17 with a light flux having a cross-sectional shape that matches with that of the image formation region 17R and has a substantially uniform intensity distribution, it is necessary to cause a light flux L having a size different from the size of the light flux incident on the image formation region 17R but having the same cross-sectional shape and intensity distribution to be incident on the light-incident-side lens 34.

In the projector 32 according to the present embodiment, which uses the light emitting apparatus 12 according to the embodiment described above, the light flux L is efficiently allowed to enter the relay system 33 disposed in a position separate from the light emitting apparatus 12.

Providing the projector 32 with the relay system 33 allows a light flux having a size that matches with the size of the image formation region 17R to be readily formed even when the size of the light emission region 12R of the light emitting apparatus 12 greatly differs from the size of the image formation region 17R of the liquid crystal display device 17. Further, since the light modulating apparatus 13 can be disposed in a position separate from the light emitting apparatus 12, the effect of the heat generated by the light emitting apparatus 12 on the light modulating apparatus 13 can be reduced.

In general, the light having passed through an optical system, such as the relay system 33, suffers attenuation of the light at the periphery, resulting in high intensity in the vicinity of the optical axis AX1 and a decrease in the intensity with distance from the optical axis AX1. When the light emitting apparatus 12 according to the embodiment described above is used, however, the intensity of the light emitted from the peripheral portion of the light emission region 12R is higher than the intensity of the light emitted from the central portion of the light emission region 12R, as shown in FIG. 8, whereby the effect of the light attenuation at the periphery due to the relay system 33 is reduced, and an image with only a small amount of brightness unevenness is likely to be produced.

### Sixth Embodiment

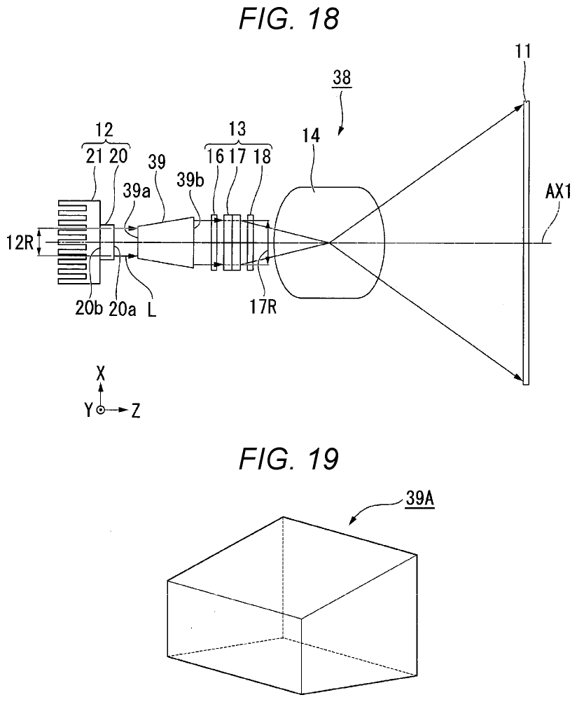

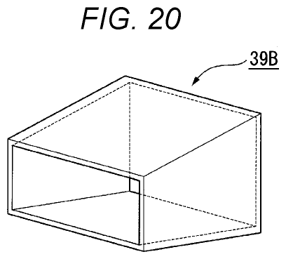

FIG. 18 is a schematic configuration diagram of the projector according to the sixth embodiment. FIG. 19 is a perspective view showing a first example of a light guide. FIG. 20 is a perspective view showing a second example of the light guide.

In FIG. 18, the components common to those in FIG. 1 used in the description of the first embodiment have the same reference characters and will not be described.

A projector 38 according to the sixth embodiment further includes a light guide 39 provided between the light emitting apparatus 12 and the light modulating apparatus 13, as shown in FIG. 18.

As the light guide 39, a light guide 39A formed of a solid rod-shaped element made of a light transmissive medium, for example, glass is used, as shown in FIG. 19. Instead, a light guide 39B formed of a hollow tubular element in which reflection mirrors are so disposed as to form a tube and cause the reflection surface to face inward is used as the light guide 39, as shown in FIG. 20. In either case, a light guide having a light incident end and a light exiting end having the same opening size and shape may be used, or a light guide so tapered that the opening size increases from the light incident end toward the light exiting end or the opening size decreases from the light incident end toward the light exiting end may be used.

A light incident end 39a and a light exiting end 39b of the light guide 39 each have a rectangular opening so set as to be substantially similar to the light emission region 12R of the light emitting apparatus 12 and the image formation region 17R of the liquid crystal display device 17. The size of the opening at the light incident end 39a of the light guide 39 is desirably equal to or slightly greater than the size of the light emission region 12R. The size of the opening at the light exiting end 39b of the light guide 39 is desirably set to be equal to or slightly greater than the size of the image formation region 17R of the liquid crystal display device 17.

In the projector 38 according to the present embodiment, using the light emitting apparatus 12 according to any of the embodiments described above allows the light flux L to efficiently enter the light guide 39 disposed in a position separate from the light emitting apparatus 12.

The light flux L having entered the light guide 39 is reflected off the interfaces or the inner wall surface of the light guide 39 multiple times and exits out of the light guide 39 with the intensity distribution of the light flux L homogenized. As a result, the intensity distribution of the light flux L is potentially further homogenized, whereby the liquid crystal display device 17 can be efficiently illuminated with the light flux L having the substantially uniform intensity. Further, since the light modulating apparatus 13 can be so disposed as to be separate from the light emitting apparatus 12, the effect of the heat generated by the light emitting apparatus 12 on the light modulating apparatus 13 can be reduced.

The technical range of the present disclosure is not limited to those in the embodiments described above, and a variety of changes can be made to the embodiments to the extent that the changes do not depart from the substance of the present disclosure.

For example, in the embodiments described above, it is assumed that the light emitting apparatus emits a light flux having uniform intensity, and the present disclosure is also applicable to a light emitting apparatus that emits light having non-uniform intensity in the light emission region. The cross-sectional shape of the light flux can be controlled by changing the light orientation angle of the light emitted from each of the resonators in consideration of the intensity of the emitted light flux.

The aforementioned third and fourth embodiments have been described with reference to the case where the first resonator is provided on the first intermediate base and the second resonator is provided on the second intermediate base. In place of the configuration described above, a plurality of resonators including the first and second resonators may be provided on one intermediate base. In this case, using a high thermal conductivity substrate, for example, an AlN substrate and an SiC substrate, facilitates dissipation of the heat from the light emitters, whereby improvement in light emission efficiency and increase in the amount of emitted light can be expected.

The embodiments described above have been described with reference to the light emitting layer made of an InGaN-based material, and any of a variety of other semiconductor materials can be used in accordance with the wavelength of the emitted light. For example, an AlGaN-based, AlGaAs-based, InGaAs-based, InGaAsP-based, InP-based, GaP-based, or AlGaP-based semiconductor material can be used. Further, the diameter of the photonic crystal structures or the intervals at which the photonic crystal structures are arranged may be changed as appropriate in accordance with the wavelength of the emitted light.

In the embodiments described above, the photonic crystal structures are each formed of a columnar structure protruding from the substrate, and a plurality of holes may be provided at fixed intervals to provide the photonic crystal effect. That is, the plurality of resonators each only need to include photonic crystal structures each having a periodical structure irrespective of whether or not the columnar structure and holes are provided.

In addition to the above, the shape, the number, the arrangement, the material, and other factors of the components of the light emitting apparatus and the projector are not limited to those in the embodiments described above and can be changed as appropriate. In the embodiments described above, the light emitting apparatus according to the present disclosure is incorporated in a projector using a transmissive liquid crystal display device as the light modulating apparatus, but not necessarily. Any of the light emitting apparatuses according to the present disclosure may be incorporated in a projector using a reflective liquid crystal display device or a digital micromirror device as the light modulating apparatus.

Further, the above embodiments have been described with reference to the case where the light emitting apparatus according to the present disclosure is incorporated in a projector, but not necessarily. The light emitting apparatus according to the present disclosure may also be used as a lighting apparatus, a headlight of an automobile, and other components.

What is claimed is:

1. A light emitting apparatus comprising:
a base; and
a plurality of resonators provided at a first surface of the base,
wherein the plurality of resonators each include a photonic crystal structure having a periodic structure,
the plurality of resonators forma light emission region that emits light resonating due to the periodic structure, and the plurality of resonators include a first resonator and a second resonator,
a distance from a center of the light emission region to the second resonator is longer than a distance from the center of the light emission region to the first resonator, and
a resonance length of the second resonator is longer than the resonance length of the first resonator.

2. The light emitting apparatus according to claim 1,
wherein the light emission region has a plurality of divided regions concentric around the center,
the plurality of divided regions include a first divided region and a second divided region,
a plurality of the first resonators are provided in the first divided region, and a plurality of the second resonators are provided in the second divided region, and
the plurality of first resonators in the first divided region have the same resonance length, and the plurality of second resonators in the second divided region have the same resonance length.

3. The light emitting apparatus according to claim 1, wherein an intensity distribution of a light flux emitted from the light emission region is so shaped that the intensity at a peripheral portion of the light emission region is higher than the intensity at a central portion of the light emission region.

4. The light emitting apparatus according to claim 1, wherein the plurality of resonators are provided on a first surface of the base via at least one intermediate base.

5. The light emitting apparatus according to claim 4,
wherein the at least one intermediate base includes a first intermediate base and a second intermediate base,
the first resonator is provided on the first intermediate base, and
the second resonator is provided on the second intermediate base.

6. The light emitting apparatus according to claim 5,
wherein the plurality of resonators include a plurality of the first resonators and a plurality of the second resonators,
the plurality of first resonators are provided on the first intermediate base, and
the plurality of second resonators are provided on the second intermediate base.

7. A projector comprising:
the light emitting apparatus according to claim 1;
a light modulating apparatus that modulates light emitted from the light emitting apparatus in accordance with image information to produce image light; and
a projection optical apparatus that projects the image light emitted from the light modulating apparatus.

8. The projector according to claim 7, wherein a planar shape of the light emission region is similar to a planar shape of an image formation region of the light modulating apparatus.

9. The projector according to claim 7, further comprising a relay system provided between the light emitting apparatus and the light modulating apparatus.

10. The projector according to claim 7, further comprising a light guide provided between the light emitting apparatus and the light modulating apparatus.
